(19) United States
(12) Patent Application Publication
(10) Pub. No.: US 2002/0168858 A1
(43) Pub. Date: Nov. 14, 2002

(54) Etching gas assistant epitaxial method

(76) Inventor: Liang-Tung Chang, Hsinchu City (TW)

Correspondence Address: Ladas & Parry, 26 West 61 Street, New York, NY, 10023, US

(21) Appl. No.: 09/954,708

(22) Filed: Sep. 17, 2001

(30) Foreign Application Priority Data
May 8, 2001 (TW) 90110943

(51) Int. Cl. H01L 21/311

(52) U.S. Cl. 438/694

(57) ABSTRACT

The present invention relates to an etching gas assistant epitaxial method, which is accomplished by introducing etching gas into the processing chamber during epitaxial deposition process. Because the etching gas has different etching rates with respect to grains of different orientations, grains with different sizes and orientations are going to be removed by the etching gas and a fine epitaxial deposited layer can thus be obtained. Furthermore, the method of the present invention can be used for depositing epitaxy on mismatched or amorphous substrates or films, such as oxide, nitride, and even metal substrates, to extend the applications of epitaxy.

### BACKGROUND OF THE INVENTION

1. Field of the Invention

The present invention relates to an etching gas assistant epitaxial method and in particular, to an epitaxial method that enables epitaxy deposited on a mismatched or amorphous substrate or film with assistance of the etching gas.

2. Description of Related Art

Epitaxial method is a grain deposition method with the outcome of good crystal structure. Conventional epitaxy needs to be deposited on a well-oriented and lattice-matched single crystal substrate. The object is let the substrate has well orientated grains as a seed for further growth of grains in sequence to achieve the demand for high quality of epitaxy. Nevertheless, a substrate with such characteristic is usually very expansive and thus, the production cost of epitaxy is kept at a high level.

Furthermore, an epitaxial method of the present day only uses growth gases on a lattice matched single crystal substrate during the process. Because the seed cannot be selected in this method, the usable substrates is limited to lattice matched materials. Thus the innovation of the technique is limited as well. There is a need to develop an innovated process to keep the eptaxial method from the substrate limitations of conventional processes.

### SUMMARY OF THE INVENTION

The object of the present invention is to provide an epitaxial method with assistance of an etching gas to control the orientation of grain growth.

Another object of the present invention is to provide an epitaxial method for epitaxy deposited on a mismatched or amorphous substrate or film and thus the applications of the epitaxy can be extended.

To overcome the shortcomings of prior art and achieve the objects mentioned above, the present invention provides an etching gas assistant epitaxial method applied mainly in a chemical vapor deposition (CVD) process. In the method of the present invention, an amorphous film is first formed on a substrate of any material, and then the etching gas is introduced by the time the epitaxy is deposited on the film to achieve the object of selecting grain's size and orientation. In this process, only grains that have greater grown speed than etched speed are remained. In other words, grains with similar size and orientation are preserved. When grains selection is accomplished, the amount of introduced etching gas is reduced gradually. Meanwhile, growth gases are still used to grow grains slowly to a required thickness. That is to say, a perfect epitaxy can be formed on any substrate by methods of the present invention and thus, the object of no limitation on substrate's material can be achieved.

### BRIEF DESCRIPTION OF THE DRAWINGS

The purpose, characteristics, and effects of the present invention will be better understood with the aid of the following description and of the drawings, in which:

FIGS. 1(a) to 1(c) are diagrams showing poly-crystalline structures etched by etching gas according to the present invention;

FIG. 2 is a flow chart of the first embodiment of the present invention;

FIG. 3 is a flow chart of the second embodiment of the present invention;

FIG. 4 is a flow chart of the third embodiment of the present invention;

FIG. 5 is a cross-sectional view of a full band solar cell's light absorbing plate produced by the method of the present invention; and

FIG. 6 is a cross-sectional view of an LD produced by the method of the present invention.

### DETAILED DESCRIPTION OF THE PREFERRED EMBODIMENT

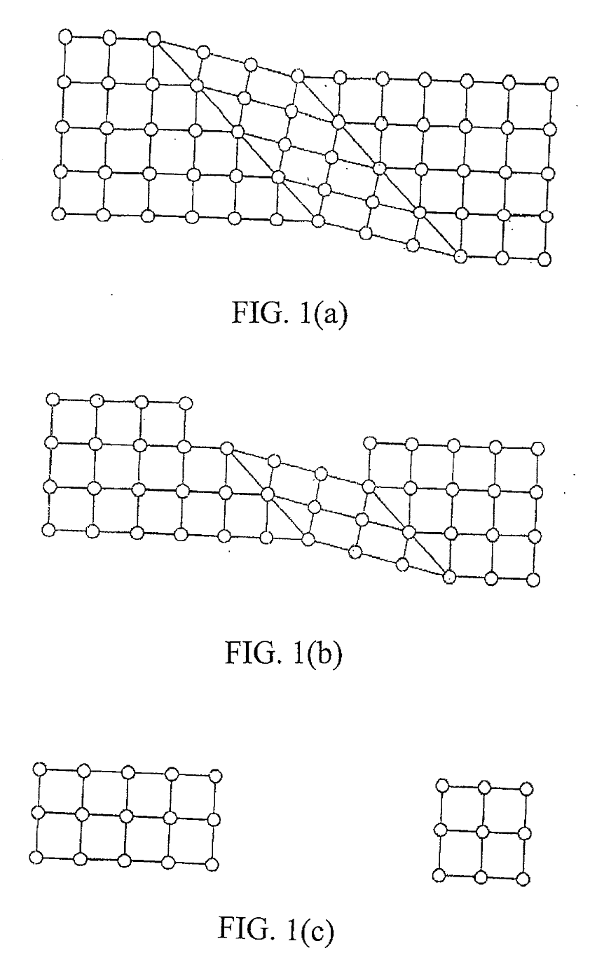

FIGS. 1(a) to 1(c) are diagrams showing poly-crystalline structures etched by etching gas according to the present invention. FIG. 1(a) is an initial poly-crystalline structure. When growth time and supplied energy for crystal growth are not sufficient, atoms or molecules cannot adjust their stacking position to the best configuration, and a structure as shown in FIG. 1(a) appears. The poly-crystalline structure has a few grains having different orientations from other grains. In general, grains with different orientations grow slower than grains with the same orientation. As FIG. 1(b) shows, by introducing an etching gas, grains with different orientation are etched away gradually. As shown in FIG. 1(c), because the grains with different orientations grow slower than the grains with the same orientation, when all the grains with different orientations are completely etched away, grains with the same orientation still exist.

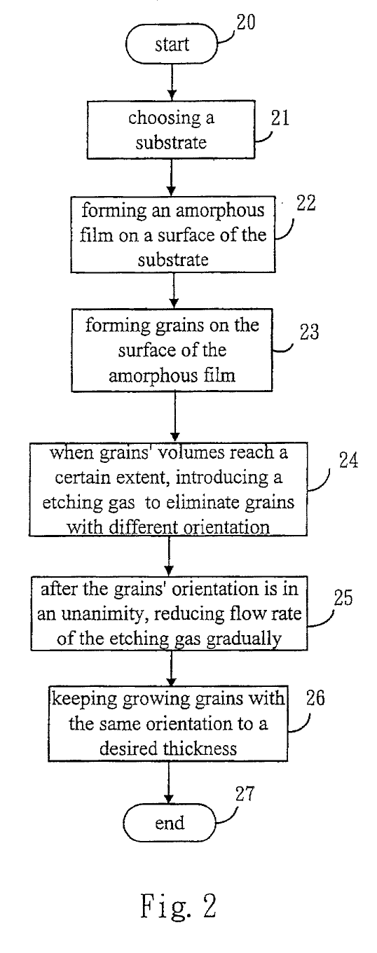

FIG. 2 is a flow chart of the first embodiment of the present invention. At step 20, the present invention starts. At step 21, a substrate is chosen. A characteristic of the present invention is the flexibility in choosing a substrate (or film). In addition to a standard lattice matched single crystal substrate, either a mismatched material or an amorphous material, such as oxide, nitride, and even metal material can be used. At step 22, an amorphous film is formed on the substrate and the thickness of the film is in the range of 0.005 μm to 1 μm. The film prevents the substrate from being etched by the etching gas introduced later, and is also the base of the following epitaxy growth. At step 23, grains are formed on the surface of the amorphous film. The method of forming grains can be either by seeding to control density of grains easily, or by introducing growth gases and raising temperature to a threshold temperature at about 280□ to 1620□ to grow crystal directly. At step 24, when the volume of the grains increases to a certain extent, the etching gas is introduced for selecting grains' size, density, and orientation. The etching gas is a compound consisting of F, Cl, Br, or I atoms, such as HCl, CCl₄, CBr₄, SiF₄, SiCl₄, HF, HBr, and etc. At this time, the flow rate of the etching gas has to be adjusted to optimize the ratio of the etching rate and growth rate of the grains, such that neither system's efficiency is lowered nor the object of selective deposition is affected. At step 25, when grains' orientation is in uniform under the function of the etching gas, the flow rate of the etching gas can be reduced gradually. At step 26, grains' volume keeps growing; nevertheless, there is still minor amount of etching gas remaining in the system, which prevents grain of different orientations from growing again. Thus grains having the same orientation can grow to a desired thickness. At step 27, the whole process ends.

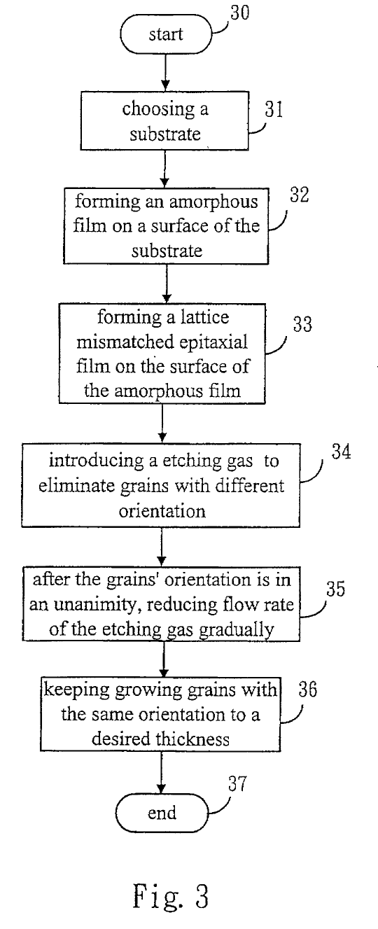

FIG. 3 is a flow chart of the second embodiment of the present invention. At step 30, the present invention starts. At step 31, a substrate is chosen. Like in the first embodiment, a mismatched or an amorphous substrate or film can be used, including oxide, nitride, and even metal material. At step 32, an amorphous film is formed on the surface of the substrate, and the thickness of the film is in a range of 0.005 μm to 1 μm. The film prevents the substrate from being etched by the etching gas introduced later and is also the base of the following epitaxy growth. At step 33, a lattice-mismatched film with thickness in the range of 0.01 μm to 1 μm is deposited. The film comprises many grains with different orientations and vacancies. At step 34, a high temperature etching gas is introduced to perform selective etching in grains' size, density, and orientation toward the film. The etching gas is a compound consisting of F, Cl, Br, or I atoms, such as HCl, CCl₄, CBr₄, SiF₄, SiCl₄, HF, HBr, and etc. At this time, the flow rate of the etching gas has to be adjusted to optimize the ratio of the etching rate and growth rate of the grains, such that neither system's efficiency is lowered nor the object of selective deposition is affected. At step 35, when grains' orientation is uniform under the function of the etching gas, the flow rate of the etching gas can be reduced gradually. At step 36, grains' volume keeps growing; nevertheless, there is still minor amount of etching gas remaining in the system. It prevents grain of different orientations from growing again and thus, grains of the same orientation can grow to a desired thickness. At step 37, the whole process ends.

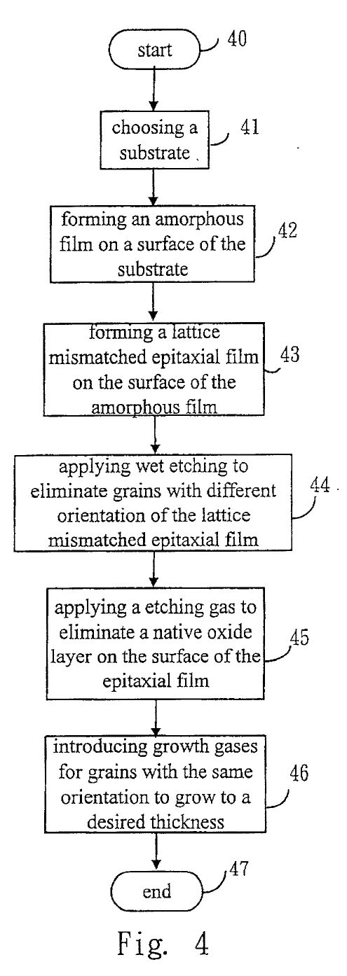

FIG. 4 is a flow chart of the third embodiment of the present invention. At step 40, the present invention starts. At step 41, a substrate is chosen. Like in the first and the second embodiments, a mismatched or an amorphous substrate or film can be used here, including oxide, nitride, and even metal material. At step 42, an amorphous film is formed on the surface of the substrate and the thickness of the film is in a range of 0.005 μm to 1 μm. The film prevents the substrate from being etched by the etching gas introduced later and is also the base of the following epitaxy growth. At step 43, a lattice-mismatched film with thickness in the range of 0.01 μm to 1 μm is deposited. The film comprises many grains with different orientations and vacancies. At step 44, to select grains' orientation of the film, the wafer is taken out from the processing chamber to proceed with wet etching. Because grains with different orientations has a higher etched rate, after a certain period of time under the function of etching solution, only grains with the same orientation remained. At step 45, the wafer is placed back to the chamber, then the chamber is degassed and required dry etching gas is injected into the chamber to etch away the native oxide formed during the wet etching of the wafer outside the chamber. At step 46, growth gases is introduced into the chamber for epitaxy to grow on the basis of the film consisted by grains with the same orientation to a required thickness. A minor amount of etching gas can be introduced at this time to prevent grains of different orientations from growing. At step 47, the whole process ends.

A key point is unveiled from the above embodiments that the etching gas is a very important element in the present invention. The present invention uses the characteristic that etching gas performs selective etching toward grains with different sizes and orientations, such that extaxy can grow on substrates which could not be used in this field in the past. To be precise, the method of the present invention makes epitaxy growth possible on substrates such as glass (Pyrex, quartz, or mixture of Al₂O₃ and SiO₂), oxide (including mixed oxide), nitride (including mixed nitride), mixed NₓO_{y} compound, and groups □-□, groups□-□, or group □ in amorphous, poly crystal, or single crystal structure. For example, Si(x)−Ge(1−x) epitaxy on a glass or a silicon substrate, SiC epitaxy on a GaAs substrate, Sapphire epitaxy on a glass substrate, and etc.

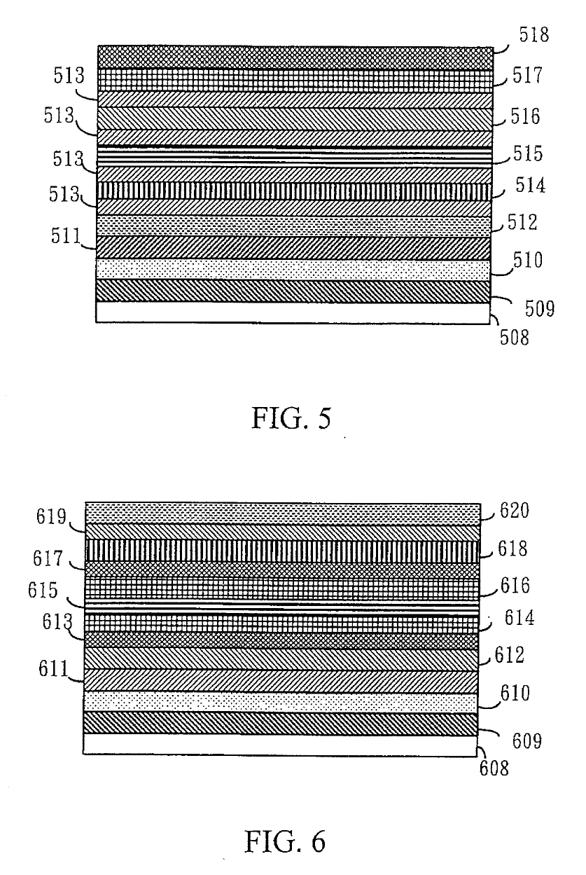

FIG. 5 is a cross-sectional view of a full band solar cell's light absorbing plate produced by the method of the present invention. The light absorbing plate consists of a plural of deposited layers, and is produced under the circumstance of pressure of 500 torr(±100%) and temperature of 900□(±80%). A substrate 510 in this embodiment is a glass. A deposited layer 509 is at the backside of the substrate 510 with a pinhole for connecting to an epitaxial layer 511. A metal layer 508 is disposed at the outermost layer of the backside of the substrate and contacts to outer environment directly during the whole process. Its thickness in the range of 0.2 μm to 20 μm. An epitaxial layer 511 is N-doped, with a thickness in the range of 0.2 μm to 20 μm. InGaAsN epitaxial layer 512 is used for absorbing sunlight that is wavelength less than 1500 nm with a thickness in the range of 0.01 μm to 20 μm. A tunneling junction layer 513 is P-doped with a thickness in the range of 0.01 μm to 1 μm. A GaAs epitaxial layer 514 is used for absorbing sunlight that wavelength is less than 850 nm, and its thickness is in the range of 0.01 μm to 20 μm. An InGaP epitaxial layer 515 is used for absorbing sunlight that wavelength is less than 650 nm, and its thickness is in the range of 0.01 μm to 20 μm. An AlInGaN epitaxial layer 516 is used for absorbing sunlight that wavelength is less than 570 nm, and its thickness is in the range of 0.01 μm to 20 μm. Another AlInGaN epitaxial layer 517 serves as the window layer of the solar cell, and it is also the conductive layer because of if s p-doped; its thickness is in the range of 0.01 μm to 20 μm. The top layer of the solar cell is a metal contact layer 518.

In the above embodiment of solar cell, the sequence of P-doped and N-doped layers can be reversed. In other words, P-doped layer is not necessarily placed on upper layers. The choice of the substrate is not limited to general glass, and glasses consist of silicon, quartz, Pyrex glass, and mixture of Al₂O₃ and SiO₂ can be used as well. Furthermore, the amount of layers can be varied in accordance with the requirement of product to improve efficiency of the solar cell. This is to say, the present invention can be applied to manufacture a full band solar cell.

FIG. 6 is a cross-sectional view of a LD produced by the method of the present invention. The LD of the present invention is produced under the circumstance of pressure of 500 torr(±100%) and temperature of 900□(±80%). A substrate 610 in this embodiment is a glass or a semiconductor material. A deposited layer 609 is at the backside of the substrate and has a pinhole for chip process. A metal layer 608 is disposed at the outermost layer of the backside of the substrate and contacts to outer environment directly, with a thickness in the range of 0.2 μm to 20 μm. An epitaxial layer 611 of group □-□ or group □-□ is a transition layer with a thickness in the range of 0.01 μm to 1 μm, which is a N-doped layer acting as a buffer layer between substrate and upper epitaxial layers. A window layer 612 is a heavy doped N contact film with a thickness in the range of 0.01 μm to 20 μm and functions as a bottom conductive layer. Reflection layers 613 and 617 possess effect of a Prague reflector, and its thickness is in the range of 0.01 μm to 5 μm. A deposition layer like layers 613 and 617 can be added or deleted in accordance with the requirement of product. An N-doped N cladding layer 614 takes the advantage of high energy level to restrict the position of electrons to prevent them from moving arbitrarily between every layer, and the thickness is in the range of 0.01 μm to 5 μm. An active region 615 is an undoped multi heterojunction structure or multi quantum well with a thickness in the range of 0.01 μm to 5 μm. The characteristic of the layer is its thicker well as a conductive layer. The function of a P-doped P cladding layer 616 is the same as the N cladding layer 614, except for the difference that it's a P-doped layer. A P-doped tunneling junction layer 618 has a thickness in the range of 0.001 μm to 1 μm. A P-doped top window layer 619 functions similarly to the window a layer 612. A contact metal layer 620 on the top of the device mainly serves as a layer for process usage, and its thickness is in the range of 0.01 μm to 20 μm.

The technical contents and features of the present invention are disclosed above. However, anyone that is familiar with the technique can modify or change the details in accordance with the present invention without departing from the technologic ideas and spirit of the invention. The protection scope of the present invention shall not be limited to what embodiment discloses, it shall include various modifications and changes that are made without departing from the technologic ideas and spirit of the invention, and shall be covered by the claims mentioned below.

What is claimed is:

1. An etching gas assistant epitaxial method, which increases selectivity of materials of a substrate with assistance of an etching gas, comprising the steps of:
(a) choosing a substrate;
(b) forming an amorphous film on a surface of the substrate;
(c) forming grains on the surface of the amorphous film;
(d) when grains' volumes reach a certain extent, introducing the etching gas to eliminate grains having different orientations;
(e) after the grains are uniform in orientation, reducing flow rate of the etching gas; and
(f) keeping growing grains with the same orientation to a desired thickness.

2. The method according to claim 1, wherein at step (a), the substrate is selected from the group consisting of oxide, nitride, NₓO_{y} compound, metal material, and lattice mismatched single crystal substrates.

3. The method according to claim 1, wherein at step (a), the substrate is of lattice mismatched, poly crystalline, or amorphous structure.

4. The method according to claim 1, wherein at step (b), a thickness of the amorphous film is in the range of 0.005 μm to 1 μm.

5. The method according to claim 1, wherein at step (c), the method for forming grains is either by seeding or by introducing growth gases to make grains grow on the amorphous film.

6. The method according to claim 1, wherein at step (d), the etching gas is a compound consisting of F, Cl, Br, or I atoms.

7. The method according to claim 1, wherein at step (d), the etching gas is selected from the group consisting of HCl, CCl₄, CBr₄, SiF₄, SiCl₄, HF, and HBr.

8. An etching gas assistant epitaxial method, which increases selectivity of materials of a substrate with assistance of an etching gas, comprising the steps of:
(a) choosing a substrate;
(b) forming an amorphous film on a surface of the substrate;
(c) forming a lattice mismatched epitaxial film on the surface of the amorphous film;
(d) introducing the etching gas to eliminate grains having different orientations;
(e) after the grains are uniform in orientation, reducing flow rate of the etching gas; and
(f) keeping growing grains with the same orientation to a desired thickness.

9. The method according to claim 8, wherein at step (a), the substrate is selected from the group consisting of oxide, nitride, NxOy compound, metal material, and lattice mismatched single crystal substrate.

10. The method according to claim 8, wherein at step (a), the substrate is of lattice mismatched, poly crystalline, or amorphous structure.

11. The method according to claim 8, wherein at step (b), a thickness of the amorphous film is in the range of 0.005 μm to 1 μm.

12. The method according to claim 8, wherein at step (c), a thickness of the lattice mismatched epitaxyial film is in the range of 0.01 μm to 1 μm.

13. The method according to claim 8, wherein at step (d), the etching gas is a compound consisting of F, Cl, Br, or I atoms.

14. The method according to claim 8, wherein at step (d), the etching gas is selected from the group consisting of HCl, CCl4, CBr4, SiF4, SiCl4, HF, and HBr.

15. An etching gas assistant epitaxial method, which increases selectivity of materials of a substrate with assistance of an etching gas, comprising the steps of:
(a) choosing a substrate;
(b) forming an amorphous film on a surface of the substrate;
(c) forming a lattice mismatched epitaxial film on the surface of the amorphous film;
(d) applying wet etching to eliminate grains having different orientations from the lattice mismatched epitaxial film;
(e) applying the etching gas to eliminate a native oxide layer on the surface of the epitaxial film; and
(f) introducing growth gases for grains having the same orientation to grow to a desired thickness.

16. The method according to claim 15, wherein at step (a), the substrate is selected from the group consisting of oxide, nitride, NxOy compound, metal material, and lattice mismatched single crystal substrate.

17. The method according to claim 15, wherein at step (a), the substrate is of lattice mismatched, poly crystalline, or amorphous structure.

18. The method according to claim 15, wherein at step (b), a thickness of the amorphous film is in the range of 0.005 μm to 1 μm.

19. The method according to claim 15, wherein at step (c), a thickness of the lattice mismatched epitaxyial film is in the range of 0.005 μm to 1 μm.

20. The method according to claim 15, wherein at step (e), the etching gas is a compound consisting of F, Cl, Br, or I atoms.

21. The method according to claim 15, wherein at step (e), the etching gas is selected from the group consisting of HCl, CCl4, CBr4, SiF4, SiCl4, HF, and HBr.
